(19) United States
(12) Patent Application Publication
(10) Pub. No.: US 2012/0242921 A1
(43) Pub. Date: Sep. 27, 2012

(54) REFLECTIVE DISPLAY AND TFT ARRAY SUBSTRATE THEREOF

(75) Inventors: CHUN-YU SHEN, Changhua County (TW); SHENG-FA LIU, Taoyuan (TW); YU-HSIEN CHEN, Kaohsiung City (TW); HUAI-AN LI, Taoyuan County (TW); BAO-SIAN CIOU, Taipei County (TW)

(73) Assignee: CHUNGHWA PICTURE TUBES, LTD., Taoyuan (TW)

(21) Appl. No.: 13/198,390

(22) Filed: Aug. 4, 2011

(30) Foreign Application Priority Data
Mar. 23, 2011 (TW) 100109824

(51) Int. Cl. G02F 1/1368; H01L 29/786

(52) U.S. Cl. 349/43; 257/59; 257/72; 257/E29.273

(57) ABSTRACT

A thin film transistor (TFT) array substrate includes a substrate and a pixel array. The pixel array is disposed on the substrate and includes a plurality of transistors and a plurality of reflective electrodes. Each transistor includes a gate, a drain, a source, and a channel layer. In each transistor, the channel layer is located between the gate and the drain, and between the gate and the source. The channel layer is partially overlapped with the gate, the drain and the source. The reflective electrodes are electrically connected to the drains respectively. Each reflective electrode includes a plurality of dyeing particles and a conductive layer. The dyeing particles are distributed in the conductive layer.

### CROSS-REFERENCE TO RELATED APPLICATION

This application claims the benefit of Taiwan Patent Application No. 100109824, filed on Mar. 23, 2011, which is hereby incorporated by reference for all purposes as if fully set forth herein.

### BACKGROUND OF THE INVENTION

1. Field of Invention

The present invention relates to a display and an element thereof, in particular, to a reflective display and a thin film transistor (TFT) array substrate thereof.

2. Related Art

A general reflective liquid crystal display (LCD) usually includes two substrates and a liquid crystal layer disposed between the two substrates. One substrate is usually a color filter substrate, and the other substrate is usually a transistor array substrate.

The color filter substrate usually has a transparent electrode and a plurality of filter layers. In the filter layers, some filter layer can filter light into red light, some filter layer can filter the light into green light, and some filter layer can filter the light into blue light. The transistor array substrate usually has a plurality of metal electrodes, and most of the metal electrodes are made of aluminum. The metal electrodes respectively correspond to the filter layers, and the liquid crystal layer is located between the transparent electrode and the metal electrodes.

When the reflective LCD is in operation, light incident from the outside firstly passes through sequentially the filter layers and the transparent electrode, and then is incident to the liquid crystal layer. At this time, the metal electrodes can generate a pixel voltage, so that an electric field is generated between the metal electrodes and the transparent electrode. Liquid crystal molecules in the liquid crystal layer are driven by the electric field to rotate, so as to control transmittance of the light incident from the outside through the liquid crystal layer. Therefore, the liquid crystal layer can allow the light to pass through or is blocking the light.

When the liquid crystal layer allows the light incident from the outside to pass through, the light is incident to the metal electrodes and reflected by the metal electrodes. The light reflected by the metal electrodes passes through sequentially the liquid crystal layer, the transparent electrode and the filter layers. Finally, the light is emitted from the reflective LCD, so that a color image enables to display.

It can be known from the foregoing that the light emitted from the reflective LCD passes through the filter layers twice, so that most energy of the light originally incident from the outside is consumed by the filter layers, thereby greatly reducing light utilization efficiency. Therefore, it causes the problems of insufficient brightness and low contrast in the reflective LCD.

### SUMMARY OF THE INVENTION

The present invention is directed to a TFT array substrate, so as to improve light utilization efficiency of a reflective display.

The present invention is further directed to a reflective display using the TFT array substrate, so as to solve the problems of insufficient brightness and low contrast.

The present invention provides a TFT array substrate including a substrate and a pixel array. The pixel array is disposed on the substrate and includes a plurality of transistors and a plurality of reflective electrodes. Each transistor includes a gate, a drain, a source, and a channel layer. In each transistor, the channel layer is located between the gate and the drain, and between the gate and the source. The channel layer is partially overlapped with the gate, the drain and the source. The reflective electrodes are electrically connected to the drains respectively. Each reflective electrode includes a plurality of dyeing particles and a conductive layer. The dyeing particles are distributed in the conductive layer.

The present invention further provides a reflective display including the foregoing TFT array substrate, a transparent substrate, a liquid material layer and a sealant. The transparent substrate includes a plate and a transparent electrode. The transparent electrode is disposed on the plate and located between the plate and the pixel array. The liquid material layer is disposed between the transparent electrode and the pixel array. The sealant surrounds the liquid material layer and is connected between the TFT array substrate and the transparent substrate.

Based on the above description, the reflective display according to the present invention uses the reflective electrodes to reflect various monochromatic lights (for example, red light, green light and blue light) so the reflective display may not need any filter layers. Therefore, the reflective display according to the present invention can reduce energy consumption of the light and improve the light utilization efficiency, thereby further solving problems of insufficient brightness and low contrast in conventional reflective LCDs.

In order to make the aforementioned features and advantages of the present invention more comprehensible, the embodiments are illustrated in detail hereinafter with reference to accompanying drawings.

### BRIEF DESCRIPTION OF THE DRAWINGS

The present invention will become more fully understood from the detailed description given herein below for illustration only, and thus are not limitative of the present invention, and wherein:

FIG. 1A is a schematic cross-sectional view of a reflective display according to a first embodiment of the present invention;

FIG. 1B is an enlarged schematic view of a reflective electrode in FIG. 1A; and

FIG. 2 is a schematic cross-sectional view of a reflective display according to a second embodiment of the present invention.

### DETAILED DESCRIPTION OF THE INVENTION

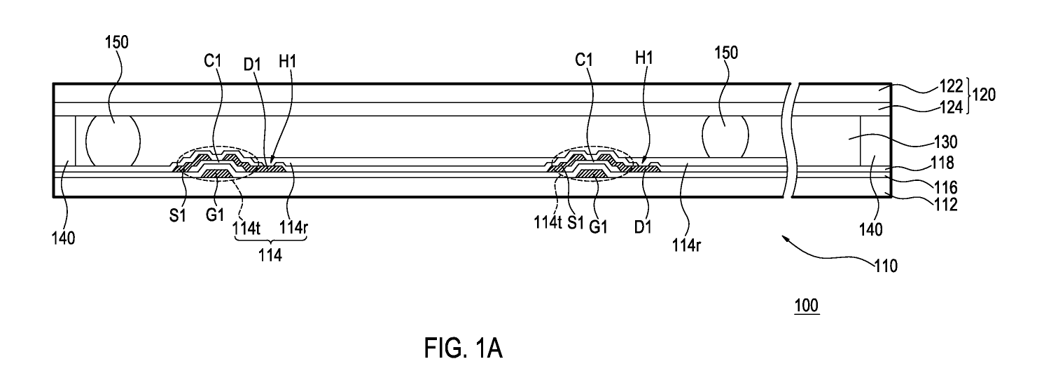

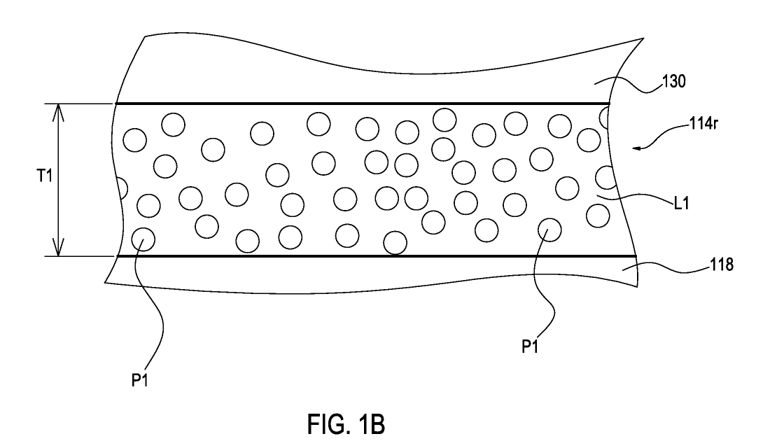

FIG. 1A is a schematic cross-sectional view of a reflective display according to a first embodiment of the present invention. Referring to FIG. 1A, the reflective display 100 according to this embodiment is a reflective LCD and includes a TFT array substrate 110, a transparent substrate 120, a liquid material layer 130, and a sealant 140. The liquid material layer 130 is disposed between the TFT array substrate 110 and the transparent substrate 120, and surrounded by the sealant 140.

The sealant 140 surrounds the liquid material layer 130 and is connected between the TFT array substrate 110 and the transparent substrate 120. Specifically, the sealant 140 may be an adhesive and thus can stick to the TFT array substrate 110 and the transparent substrate 120. Therefore, the sealant 140 can combine the TFT array substrate 110 and the transparent substrate 120 together and sealing the liquid material layer 130, so as to prevent the liquid material layer 130 from leakage.

The TFT array substrate 110 includes a substrate 112 and a pixel array 114, and the pixel array 114 is disposed on the substrate 112 and includes a plurality of transistors 114t and a plurality of reflective electrodes 114r. The transistors 114t may all be field-effect transistors (FETs), and thus each transistor 114t includes a gate G1, a drain D1, a source 51 and a channel layer C1. In each transistor 114t, the channel layer C1 is located between the gate G1 and the drain D1, and between the gate G1 and the source 51. The channel layer C1 is partially overlapped with the gate G1, the drain D1 and the source 51.

The reflective electrodes 114r are electrically connected to the drains D1 respectively, and therefore the transistors 114t are able to control an electrical signal for inputting into the reflective electrodes 114r, so as to enable the reflective electrodes 114r to generate a pixel voltage. Furthermore, the reflective electrodes 114r are able to reflect monochromatic lights with specific wavelengths, and the wavelengths of the lights generated reflected by the reflective electrodes 114r are not the same. For example, some reflective electrodes 114r are capable of reflecting red light, some reflective electrodes 114r are capable of reflecting green light, and some reflective electrodes 114r are capable of reflecting blue light.

FIG. 1B is an enlarged schematic view of a reflective electrode in FIG. 1A. Referring to FIG. 1A and FIG. 1B, each reflective electrode 114r includes a conductive layer L1 and a plurality of dyeing particles P1, and the dyeing particles P1 are distributed in the conductive layer L1. The material of the conductive layer L1 may include a plurality of conductive particles, such as a plurality of nano silver particles or a plurality of nano gold particles. In other words, the conductive layer L1 may be formed by the nano silver particles or the nano gold particles. Therefore, all the reflective electrodes 114r are conductors and able to receive the electrical signal from the transistors 114t, thereby generating the pixel voltage.

The material of the dyeing particles P1 may include a dye such as methyl red, and the dyeing particles P1 vary from each other in color. For example, some dyeing particles P1 are shown in red, some dyeing particles P1 are shown in green, and some dyeing particles P1 are shown in blue. Therefore, some reflective electrodes 114r can reflect the red light, some reflective electrodes 114r can reflect the green light, and some reflective electrodes 114r can reflect the blue light.

The reflective electrodes 114r may be formed by using an inkjet printing method. Specifically, in the method for forming the reflective electrodes 114r, a plurality of colored pigments may be sprayed on the substrate 112, for example, a red pigment, a green pigment and a blue pigment. The colored pigments are, for example opaque pigments, and may be formed by mixing dye solution and conductive nano ink, in which the conductive nano ink contains conductive particles such as a plurality of nano silver particles or a plurality of nano gold particles.

The viscosities of the colored pigments may range from 10 centi-poises (cp) to 20 cp, and solid contents of both the dye solution and the conductive nano ink may range from 30 wt % to 50 wt % of the entire colored pigments, in which a ratio of the dye solution to the conductive nano ink may be about 1:15. After the spraying of the colored pigments is completed, a solvent in the colored pigments are volatilized, for example, drying the colored pigments. In this way, the reflective electrodes 114r are formed.

Furthermore, the thickness T1 of the reflective electrodes 114r may be larger than the thickness of the metal electrodes of the conventional reflective LCD. For example, the thickness T1 of the reflective electrodes 114r may be larger than 50 nanometers. In this way, the light transmittance of the reflective electrodes 114r can be reduced, and even the reflective electrodes 114r are enabled to completely block the light, thereby increasing color saturation of the reflective display 100.

The TFT array substrate 110 as shown in FIG. 1A is a bottom-gate type transistor array substrate. Specifically, the gates G1 are all disposed on the substrate 112 and in contact with the substrate 112. The channel layers C1 are respectively located above the gates G1, and the drains D1 and the sources S1 are respectively disposed on the channel layers C1.

The TFT array substrate 110 further includes a gate dielectric layer 116 and an insulating layer 118. The gate dielectric layer 116 covers the gates G1, and the channel layers C1 are disposed on the gate dielectric layer 116. The insulating layer 118 is disposed on the substrate 112 and covers the transistors 114t, and the reflective electrodes 114r are all disposed on the insulating layer 118. The conductive layers L1 are all in contact with the insulating layer 118, as shown in FIG. 1B.

In addition, the insulating layer 118 may have a plurality of contact holes H1, as shown in FIG. 1A, and each contact hole H1 is located above one of the drains D1. The reflective electrodes 114r respectively extend into the contact holes H1, and respectively are in contact with and connected to the drains D1. In other words, the reflective electrodes 114r can be electrically connected to the transistors 114t respectively through the contact holes H1, thereby enabling to receive the electrical signal from the transistors 114t.

It is worth mentioning that although the TFT array substrate 110 shown in FIG. 1A is the bottom-gate type transistor array substrate, the TFT array substrate 110 may also be a top-gate type transistor array substrate in other embodiments. That is to say, the reflective electrodes 114r may also be applied to the top-gate type transistor array substrate. Therefore, the TFT array substrate 110 shown in FIG. 1A is only taken as an example, and not intended to limit the present invention.

The transparent substrate 120 includes a plate 122 and a transparent electrode 124. The transparent electrode 124 is disposed on the plate 122, and is located between the plate 122 and the pixel array 114. The liquid material layer 130 is disposed between the transparent electrode 124 and the pixel array 114, and is a liquid crystal layer containing a plurality of liquid crystal molecules. Therefore, the reflective electrodes 114r capable of generating the pixel voltage may generate an electric field in the liquid material layer 130, so as to control the transmittance of light incident from the outside through the liquid material layer 130. In this way, the liquid material layer 130 allows the light to pass through or blocks the light. Furthermore, the light incident from the outside may be, for example, white light or natural light.

The light incident from the outside passes through the transparent substrate 120 at first, and then is incident to the liquid material layer 130. When the liquid material layer 130 allows the light incident from the outside to pass through, the light will be incident to the reflective electrodes 114r and then be reflected by the reflective electrodes 114r to generate various monochromatic lights with specific wavelengths, for example, red light, green light and blue light. When the monochromatic lights are generated by the reflection of the reflective electrodes 114r, the monochromatic lights will pass through again the transparent substrate 120 and then be emitted from the reflective display 100, thereby enabling a color image to be displayed.

Based on the above description, the reflective display 100 uses the reflective electrodes 114r, thereby enabling to generate various monochromatic lights (for example, red light, green light and blue light) by reflection under a condition without using any filter layers. Although the lights emitted from the reflective display 100 have passed through the transparent substrate 120 twice, the reflective display 100 does not use any filter layers so that the lights do not pass through any filters. Compared with the conventional reflective LCD, the reflective display 100 is able to reduce the energy consumption of the light to improve the light utilization efficiency, thereby solving the problems of insufficient brightness and low contrast in the conventional reflective LCD.

In addition, the reflective display 100 may further include a plurality of spacers 150. The spacers 150 are disposed in the liquid material layer 130 and are in contact with the TFT array substrate 110 and the transparent substrate 120. The spacers 150 located on the TFT array substrate 110 are able to support the transparent substrate 120, so as to maintain a gap between the TFT array substrate 110 and the transparent substrate 120, so that the liquid material layer 130 is disposed between the TFT array substrate 110 and the transparent substrate 120. Moreover, the spacers 150 may be ball spacers or photo spacers (PSs).

The foregoing reflective display 100 is a reflective LCD, which means the TFT array substrate 110 may be applied to the reflective LCD. However, in addition to the reflective LCD, the TFT array substrate 110 may also be applied to reflective displays in other types, for example, an electrowetting display. Thus, the type of the reflective display 100 as shown in FIG. 1A is only taken as an example, and not intended to limit the present invention.

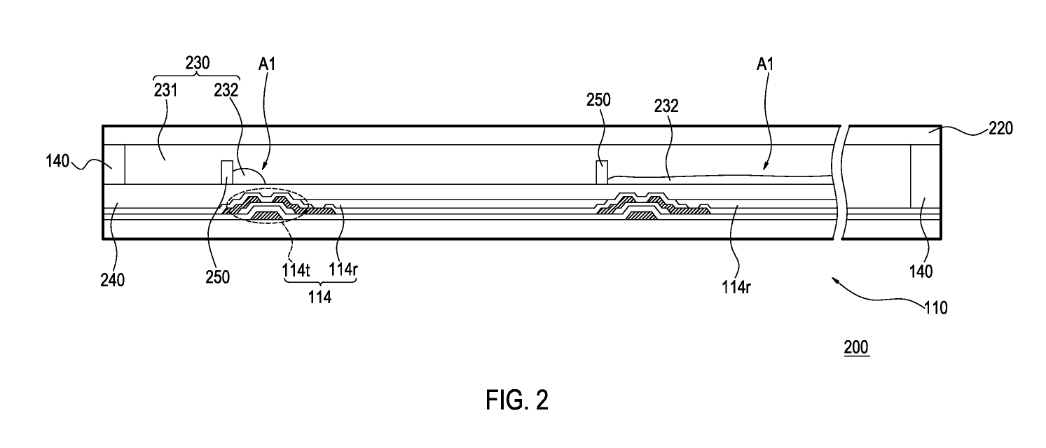

FIG. 2 is a schematic cross-sectional view of a reflective display according to a second embodiment of the present invention. Referring to FIG. 2, although the reflective display 200 according to this embodiment and the reflective display 100 both include the TFT array substrate 110 and the sealant 140, the reflective display 200 is a display different from the reflective display 100 and is an electrowetting display.

Specifically, the reflective display 200 further includes a transparent substrate 220, a liquid material layer 230, a hydrophobic dielectric layer 240 and a plurality of baffles 250. It is different from the reflective display 100 as shown in FIG. 1A that the transparent substrate 220 is, for example, a glass plate, and may have no transparent electrode 124. The liquid material layer 230 includes a polar liquid 231 and a plurality of nonpolar liquids 232. The polar liquid 231 is, for example, deionized water or ordinary aqueous solution, and the nonpolar liquids 232 are, for example, ink or other oily solution, so the polar liquid 231 and the nonpolar liquids 232 are insoluble with each other.

The hydrophobic dielectric layer 240 is disposed on the pixel array 114, and the liquid material layer 230 is located on the hydrophobic dielectric layer 240, so the hydrophobic dielectric layer 240 is located between the pixel array 114 and the liquid material layer 230. The baffles 250 are disposed on the hydrophobic dielectric layer 240 and define a plurality of pixel areas A1 on the hydrophobic dielectric layer 240. Furthermore, the hydrophobic dielectric layer 240 may be transparent, so the color of each reflective electrode 114r can be seen in the view from the hydrophobic dielectric layer 240 to the reflective electrodes 114r.

The pixel areas A1 respectively correspond to the reflective electrodes 114r. Taking FIG. 2 as an example, each pixel area A1 is located just above one of the reflective electrodes 114r. Each nonpolar liquid 232 is located in one of the pixel areas A1, and the polar liquid 231 covers the baffles 250 and the nonpolar liquids 232. The baffles 250 may be made of a hydrophilic material.

The color of the nonpolar liquids 232 may be black. When the reflective display 200 is in operation and an image is displayed thereon, some reflective electrodes 114r (for example, reflective electrodes 114r on the left side as shown in FIG. 2) generate a pixel voltage. At this time, the reflective electrodes 114r generating the pixel voltage enable the hydrophobic dielectric layer 240 to attract the polar liquid 231, and the attracted polar liquid 231 squeezes the nonpolar liquids 232, thereby reducing an area where the nonpolar liquid 232 (for example, a nonpolar liquid 232 on the left side as shown in FIG. 2) occupies one of the pixel areas A1. In this way, the pixel area A1 may display a color with a high gray level value.

In addition, when the reflective display 200 is in operation and an image is displayed thereon, the other reflective electrodes 114r (for example, reflective electrodes 114r on the right side as shown in FIG. 2) do not generate a pixel voltage. At this time, the polar liquid 231 repels the hydrophobic dielectric layer 240, but the nonpolar liquids 232 are attracted by the hydrophobic dielectric layer 240, thereby increasing an area where the nonpolar liquid 232 (for example, a nonpolar liquid 232 on the right side as shown in FIG. 2) occupies another pixel area A1. In this way, the pixel areas A1 may display a color with a low gray level value or a low gray level, for example, black.

To sum up, in the reflective display according to the present invention, the above reflective electrodes are used to generate various monochromatic lights (for example, red light, green light, and blue light) by reflection, so the reflective display according to the present invention does not use any filter layers. Compared with the conventional reflective LCD, the lights emitted from the reflective display according to the present invention do not pass through any filters, thereby reducing the energy consumption of the lights and improving the light utilization efficiency, further solving the problems of the insufficient brightness and the low contrast in the conventional reflective LCD.

Although the present invention has been disclosed through the preferable embodiments, they are not intended to limit the present invention. Equivalent replacements of variations and modifications made by persons skilled in the art without departing from the spirit and the scope of the present invention still fall within the protection scope of the present invention.

What is claimed is:

1. A thin film transistor (TFT) array substrate, comprising:
a substrate;
a pixel array, disposed on the substrate and comprising:
a plurality of transistors, wherein each of the transistors comprises a gate, a drain, a source, and a channel layer; in each of the transistors, the channel layer is located between the gate and the drain, and between the gate and the source; and the channel layer is partially overlapped with the gate, the drain, and the source; and
a plurality of reflective electrodes, electrically connected to the drains respectively, wherein each of the reflective electrodes comprises a conductive layer and a plurality of dyeing particles, and the dyeing particles are distributed in the conductive layer.

2. The TFT array substrate according to claim 1, further comprising: an insulating layer disposed on the substrate and covering the transistors, wherein the reflective electrodes are disposed on the insulating layer, and the conductive layers are in contact with the insulating layer.

3. The TFT array substrate according to claim 2, wherein the insulating layer has a plurality of contact holes, each of the contact holes is located above one of the drains, and the reflective electrodes respectively extend into the contact holes and are respectively in contact with and connected to the drains.

4. The TFT array substrate according to claim 1, wherein the gates are in contact with the substrate, the channel layers are respectively located above the gates, and the drains and the sources are respectively disposed on the channel layers.

5. The TFT array substrate according to claim 4, further comprising: a gate dielectric layer covering the gates, wherein the channel layers are disposed on the gate dielectric layer.

6. The TFT array substrate according to claim 1, wherein a material of the conductive layers comprises a plurality of nano silver particles or a plurality of nano gold particles.

7. The TFT array substrate according to claim 1, wherein a material of the dyeing particles comprises a methyl red.

8. The TFT array substrate according to claim 1, wherein thickness of the reflective electrodes is larger than 50 nanometers.

9. A reflective display, comprising:
the TFT array substrate, comprising:
a substrate;
a pixel array, disposed on the substrate and comprising:
a plurality of transistors, wherein each of the transistors includes a gate, a drain, a source, and a channel layer; in each of the transistors, the channel layer is located between the gate and the drain, and between the gate and the source; and the channel layer is partially overlapped with the gate, the drain, and the source;
a plurality of reflective electrodes, electrically connected to the drains respectively, wherein each of the reflective electrodes comprises a conductive layer and a plurality of dyeing particles, and the dyeing particles are distributed in the conductive layer;
a transparent substrate, comprising a plate and a transparent electrode, wherein the transparent electrode is disposed on the plate and located between the plate and the pixel array;
a liquid material layer, disposed between the transparent electrode and the pixel array; and
a sealant, surrounding the liquid material layer and connected between the TFT array substrate and the transparent substrate.

10. The reflective display according to claim 9, wherein the liquid material layer is a liquid crystal layer.

11. The reflective display according to claim 10, further comprising: a plurality of spacers disposed in the liquid material layer and in contact with the TFT array substrate and the transparent substrate.

12. The reflective display according to claim 9, further comprising:
a hydrophobic dielectric layer, disposed on the pixel array; and
a plurality of baffles, disposed on the hydrophobic dielectric layer and defining a plurality of pixel areas on the hydrophobic dielectric layer, wherein the pixel areas respectively correspond to the reflective electrodes, the liquid material layer is located on the hydrophobic dielectric layer and comprises a polar liquid and a plurality of nonpolar liquids, each of the nonpolar liquids is located in one of the pixel areas, and the polar liquid covers the baffles and the nonpolar liquids.
